(19) United States
(12) Patent Application Publication
(10) Pub. No.: US 2003/0044532 A1
(43) Pub. Date: Mar. 6, 2003

(54) Process for preparing porous low dielectric constant material

(76) Inventors: Shyh-Dar Lee, Hsinchu Hsien (TW); Chen-Chiu Hsue, Hsinchu (TW)

Correspondence Address: BIRCH STEWART KOLASCH & BIRCH, PO BOX 747, FALLS CHURCH, VA, 22040-0747, US

(21) Appl. No.: 10/145,716

(22) Filed: May 16, 2002

(30) Foreign Application Priority Data
Aug. 29, 2001 (TW) 90121280

(51) Int. Cl. C23C 16/00; B05D 3/02

(52) U.S. Cl. 427/248.1; 427/372.2

(57) ABSTRACT

A process for preparing a porous low dielectric constant material. The process mainly uses critical point drying technique. By changing the pressure and temperature, a liquid component is released from a specific wet film composition. Thus, a porous low dielectric constant material is obtained.

### BACKGROUND OF THE INVENTION

1. Field of the Invention:

The present invention relates to a process for preparing a dielectric material, and more particularly to a process for preparing a porous low dielectric constant material.

2. Description of the Prior Art:

As feature sizes in integrated circuits approach 0.18 μm and below, problems with RC (resistance-conductance) delay time have become increasingly difficult to resolve. In order to decrease the RC delay, one method is to use a low resistance conductive material to fabricate conductive lines, for example, to use a copper process. Another method is to use a low-k material to serve as the inter-metal dielectric (IMD). The present trend is to use a dielectric material with a porous structure to prepare the IMD to meet the requirements of low dielectric constant. Therefore, the way on how to prepare a porous low dielectric constant material is still a major course in Ultra Large Scale Integration (ULSI) technology.

Presently, low dielectric constant material is mainly prepared by spin-on coating using silicon dioxide, and the obtained material is called spin-on glass (SOG). Also, low dielectric constant silicon dioxide layer can be deposited by plasma-enhanced chemical vapor deposition (PECVD) or high density plasma PECVD (HDP PECVD). However, such material has a refractive index of about 1.46, and the silicon dioxide structure is close packed. Thus, the dielectric constant is about 4, which can not achieve a porous structure.

### SUMMARY OF THE INVENTION

The object of the present invention is to solve the above-mentioned problems and to provide a process for preparing a porous low dielectric constant material. The process mainly uses critical point drying technique. By changing the pressure and temperature, a liquid component is released from a specific wet film composition. Thus, a porous low dielectric constant material is obtained.

Another object of the present invention is to provide a process for preparing a porous low dielectric constant material. The low dielectric constant material obtained has advantages of high stability, crack-resistance, high hardness, good adhesion, low thermal expansion coefficient, and can be compatible with CMP process. Also, the process is simple and cost is low.

To achieve the above-mentioned objects, the process for preparing a porous low dielectric constant material of the present invention includes the following steps. First, a specific wet film composition is formed on a substrate. A liquid gas is introduced such that the liquid gas is thoroughly mixed with the liquid component in the wet film composition. By changing the pressure and temperature, the liquid gas is made to evaporate and the liquid component in the wet film composition is also released, accompanied by the evaporation of the liquid gas. Thus, the liquid component is released from the wet film composition in a critical point dry (CPD) manner. The wet film composition is then baked and cured to form a porous low dielectric constant material.

### BRIEF DESCRIPTION OF THE DRAWINGS

The present invention will become more fully understood from the detailed description given hereinbelow and the accompanying drawings, given by way of illustration only and thus not intended to be limitative of the present invention.

FIGS. 1A to 1G are cross-sections illustrating the process flow of preparing a porous low dielectric constant material according to an embodiment of the present invention.

### DETAILED DESCRIPTION OF THE PREFERRED EMBODIMENTS

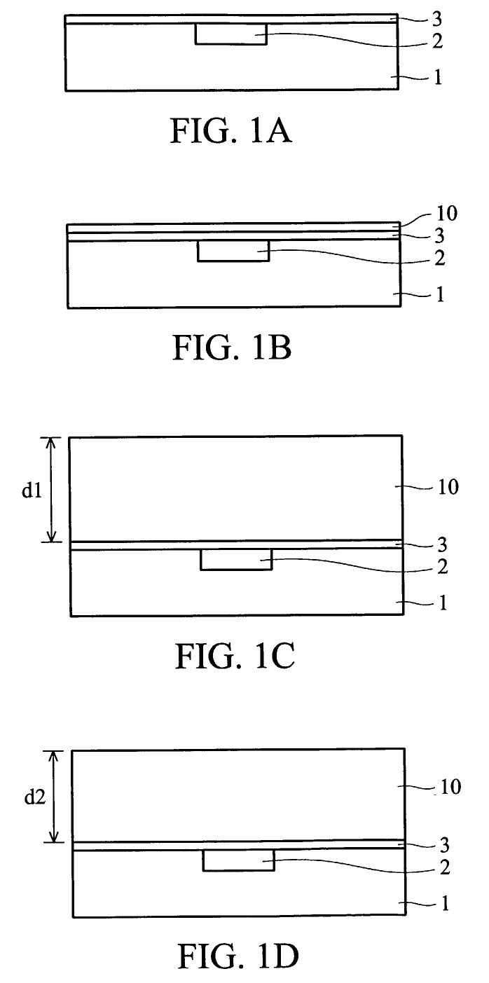

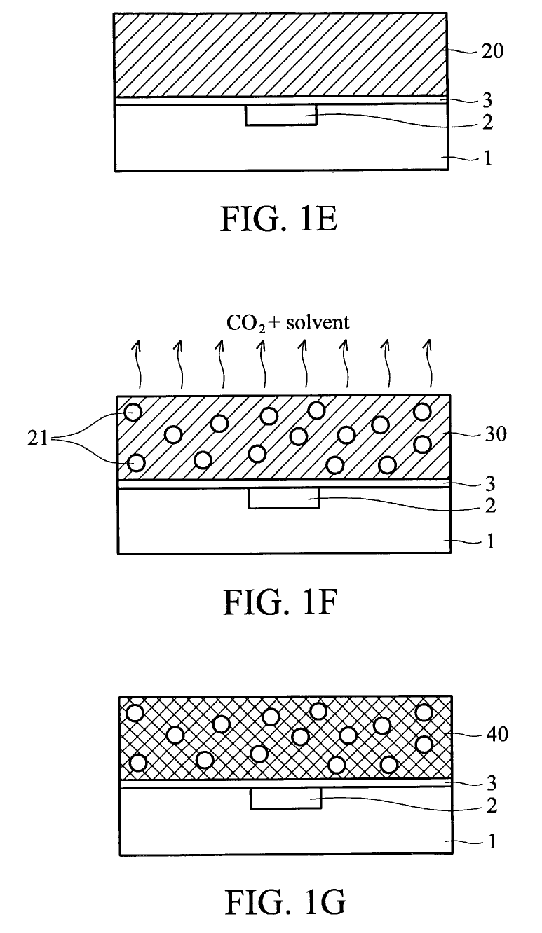

FIGS. 1A to 1G show cross-sections illustrating the process flow according to an embodiment of the present invention.

Step 1:

First, a substrate 1 is provided as a start material. The substrate can be simply a substrate itself or can be a substrate on which specific devices, wirings, or structures have been formed using specific semiconductor processes.

In this embodiment, the substrate 1 can be a semiconductor substrate, such as a silicon substrate, and a copper layer 2 and a silicon nitride insulating layer 3 are formed on the substrate 1, as shown in FIG. 1A.

Step 2:

A first composition 10 that contains a liquid component is formed on the substrate 1, as shown in FIG. 1B.

The first composition 10 can be a silicon oxide solution composition or a carbon-containing organic solution composition. In this embodiment, silica gel is selected as the first composition 10. The silica gel is formed by dissolving SiO₂ in a specific solvent. The specific solvent can be IPA (isopropyl alcohol).

In addition, the first composition 10 can be formed on the substrate 1 by spraying, spin-on, or injection.

Step 3:

The thickness of the first composition 10 is increased, such that the first composition 10 is a wet film with a thickness of d1, as shown in FIG. 1C.

Step 4:

The first composition 10 is subjected to soft baking. This can partially remove the liquid component in the first composition 10. For example, 80% of IPA is removed. Also, the thickness of the first composition 10 (the wet film) can be adjusted to a specific thickness (d2), as shown in FIG. 1D.

Step 5:

The atmosphere pressure is increased to a first pressure. A liquid gas is introduced into the first composition 10 at the first pressure to obtain a second composition 20, as shown in FIG. 1E. The liquid gas suitable for use can be liquid carbon dioxide (CO₂), liquid nitrogen (N₂), or liquid carbon monoxide (CO). The first pressure is preferably higher than the critical pressure of the liquid gas.

In this embodiment, the atmosphere pressure is increased to 20 atm (the first pressure), and then liquid carbon dioxide is introduced. The liquid carbon dioxide is thoroughly mixed with the liquid component (solvent IPA) in the first composition 10 to achieve solvent transfer.

Step 6:

The first pressure is changed to convert the liquid CO₂ into CO₂ gas 21 and evaporate the CO₂ gas. When the liquid CO₂ converts into a gas form and evaporates from the second composition 20, the liquid component (solvent IPA) is also released from the second composition. Thus, the second composition 20 converts into a third composition 30, as shown in FIG. 1F.

Preferably, the first pressure is decreased to the critical pressure of the liquid gas, such that the liquid gas converts into a gas form and evaporates. In this embodiment, the first pressure is 20 atm and then is decreased to the critical pressure of the liquid CO₂ (about 5 atm). Thus, the liquid CO₂ converts into CO₂ gas and evaporates.

When the CO₂ gas evaporates from the second composition 20, the liquid component (solvent IPA) is also released from the second composition 20. This results in critical point dry of the second composition 20. Thus, the third composition 30 with a roughly porous structure is obtained.

It should be noted that in order to control the surface uniformity of the third composition 30, when the first pressure (20 atm) is decreased to the second pressure (5 atm), the entire material must be maintained at the second pressure (5 atm) for a predetermined period of time to make the CO₂ gas start to evaporate slowly. Afterwards, the second pressure (5 atm) is further decreased to such as 2 atm. This can prevent crater-shaped protrusion defects on the surface of the third composition 30 resulting from too fast evaporation of the CO₂ gas.

Step 7:

The third composition 30 is baked to dry. Thus, a fourth composition 40 with a porous structure is formed as shown in FIG. 1G. The baking is conducted at a pressure of 1 atm.

The step of baking the third composition 30 is conducted at a temperature equal to or higher than the boiling point of the liquid component (solvent IPA) in the first composition 10. In this embodiment, the boiling point of IPA is about 40° C. Therefore, the third composition 30 can be baked at a temperature higher than 40° C., for example, at 75° C. This makes the residual IPA solvent evaporate from the third composition 30 to obtain the fourth composition 40 with a porous structure.

Alternatively, the third composition 30 can be baked in a discontinuous/gradient way. That is, the third composition 30 is heated from a low temperature to a high temperature and maintained at a temperature between the low and high temperatures for a predetermined period of time. Thus, a better throughput can be obtained. For example, the third composition can be baked at 75° C. for 30 seconds, then heated to 150° C. and baked at 150° C. for 30 seconds, and heated to 250° C. and finally baked at 250° C. for 30 seconds.

The fourth composition 40 obtained from baking contains mainly SiO₂. Since the fourth composition has a special porous structure, it can provide a relatively low dielectric constant.

Step 8:

Finally, the fourth composition 40 is cured to obtain a low dielectric constant material with a porous structure.

The curing of the fourth composition can be conducted at a temperature of 250° C. to 450° C. for 1 to 90 minutes. In this embodiment, if the curing is conducted in a furnace, it can be performed at 400° C. for 30 minutes. If the curing is conducted in a single-wafer reactor, it can be performed at 425° C. for 1 minute.

According to experimental results, the porous low dielectric constant material prepared from the present invention has the following basic properties: dielectric constant is about 1.8 (analyzed by an ellipsometer), refractive index is about 1.2, thermal stability is higher than 350° C. (analyzed by TGA and TDS), thermal contraction is about 2% (after three times of heating cycle from 25° C. to 420° C.), and hardness is about 2-3 Gpa.

According to the above embodiment, the porous low dielectric constant material obtained from the present invention mainly contains SiO₂ and has the advantages of high stability, crack-resistance, high hardness, good adhesion, and low thermal expansion coefficient. In addition, the porous low dielectric constant material can be compatible with the chemical mechanical polishing (CMP) process. Moreover, the porous low dielectric material does not generate toxic gas when a via hole is formed.

In addition, the porous low dielectric constant material of the present invention has a simple process and low cost. Therefore, it can be widely utilized in various applications, such as damascene process of integrated circuits, liquid crystal displays, and communication (high frequency) integrated circuits, etc.

The foregoing description of the preferred embodiments of this invention has been presented for purposes of illustration and description. Obvious modifications or variations are possible in light of the above teaching. The embodiments were chosen and described to provide the best illustration of the principles of this invention and its practical application to thereby enable those skilled in the art to utilize the invention in various embodiments and with various modifications as are suited to the particular use contemplated. All such modifications and variations are within the scope of the present invention as determined by the appended claims when interpreted in accordance with the breadth to which they are fairly, legally, and equitably entitled.

What is claimed is:

1. A process for preparing a porous low dielectric constant material, comprising the following steps:
providing a substrate;
forming a first composition that contains a liquid component on the substrate;
introducing a liquid gas into the first composition at a first pressure to form a second composition;
changing the first pressure to make the liquid gas evaporate, wherein when the liquid gas evaporates from the second composition, the liquid component is released from the second composition, thus forming a third composition;
baking the third composition to form a fourth composition with a porous structure; and
curing the fourth composition.

2. The process as claimed in claim 1, wherein after the first composition is formed, further comprising baking the first composition to partially remove the liquid component in the first composition and to adjust the thickness of the first composition.

3. The process as claimed in claim 1, wherein the liquid gas is liquid carbon dioxide, liquid nitrogen, or liquid carbon monoxide.

4. The process as claimed in claim 1, wherein the first pressure is higher than the critical pressure of the liquid gas.

5. The process as claimed in claim 4, wherein the step of changing the first pressure includes decreasing the first pressure to a second pressure, maintaining at the second pressure for a predetermined period of time, and then continuing decreasing the second pressure.

6. The process as claimed in claim 5, wherein the second pressure is the critical pressure of the liquid gas.

7. The process as claimed in claim 1, wherein the step of baking the third composition is conducted at a temperature equal to or higher than the boiling point of the liquid component in the first composition.

8. The process as claimed in claim 1, wherein the step of baking the third composition is conducted in a discontinuous/gradient way and the third composition is heated from a low temperature to a high temperature and maintained at a temperature between the low and high temperatures for a predetermined period of time.

9. The process as claimed in claim 1, wherein the step of curing the fourth composition is conducted at a temperature of 250° C. to 450° C. for 1 to 90 minutes.

10. The process as claimed in claim 1, wherein the first composition is a silicon oxide solution composition or a carbon-containing organic solution composition.
